(19) United States
(12) Patent Application Publication
(10) Pub. No.: US 2016/0049484 A1
(43) Pub. Date: Feb. 18, 2016

(54) SEMICONDUCTOR DEVICE

(71) Applicant: KABUSHIKI KAISHA TOSHIBA, Tokyo (JP)

(72) Inventors: Yukie NISHIKAWA, Nonoichi Ishikawa (JP); Yasuhiko AKAIKE, Kanazawa Ishikawa (JP)

(21) Appl. No.: 14/634,864

(22) Filed: Mar. 1, 2015

(30) Foreign Application Priority Data
Aug. 18, 2014 (JP) 2014-165984

(51) Int. Cl. H01L 29/423; H01L 29/66; H01L 29/78

(52) U.S. Cl. CPC H01L 29/4236; H01L 29/7831; H01L 29/66666

(57) ABSTRACT

A semiconductor device includes a second conductivity-type second semiconductor layer selectively provided on a first conductivity-type first semiconductor layer, a first conductivity-type third semiconductor layer provided on the second semiconductor layer, and at least one control electrode that is spaced from the second semiconductor layer and the third semiconductor layer by an insulating film. In addition, the semiconductor device further includes a second conductivity-type fourth semiconductor layer provided on a side of the control electrode opposite to a side thereof where the second semiconductor layer is located, and a semiconductor region that is provided between the first semiconductor layer and the fourth semiconductor layer, the first semiconductor layer making contact in the insulating film at the bottom of the control electrode, and containing at least one type of electrically inactive element in at least any one of the first semiconductor layer and the fourth semiconductor layer.

### CROSS-REFERENCE TO RELATED APPLICATION

This application is based upon and claims the benefit of priority from Japanese Patent Application No. 2014-165984, filed Aug. 18, 2014, the entire contents of which are incorporated herein by reference.

### FIELD

Embodiments described herein relate generally to semiconductor devices.

### BACKGROUND

A semiconductor device that is used for switching of electric power or the like is called a power semiconductor device, and it is used for various purposes such as installation on vehicles and a smart grid. The power semiconductor device is required to have low-loss characteristics (a low forward voltage Vf), high-speed characteristics (high switching speed), and high breakdown voltage characteristics and so on. For example, an injection enhanced gate transistor (IEGT) with a trench gate structure is suitable for a use that is required to have a high breakdown voltage and high-speed characteristics. Some IEGTs are provided with a P-type floating layer that is placed between trenches. The p-type floating layer enhances the accumulation of carriers and achieves low-loss characteristics for the device. For this reason, it is preferable that the floating layer is formed to have a greater depth inwardly of the device than the gate electrodes. However, if the P-type impurities of the floating layer are diffused deeply, the floating layer can extend across the gate electrode and connect to a base layer on an opposite side of the gate electrode, which sometimes degrades the characteristics of the IEGT.

### DESCRIPTION OF THE DRAWINGS

FIG. 1 is a schematic cross-sectional view illustrating a semiconductor device according to an embodiment.

FIGS. 2A to 2C are schematic cross-sectional views each illustrating the semiconductor device during steps in the production process of the semiconductor device.

FIGS. 3A and 3B are schematic cross-sectional views each illustrating the semiconductor device during steps in the production process following the production process of FIG. 2.

FIGS. 4A and 4B are schematic diagrams each illustrating the characteristics of the semiconductor device according to the embodiment.

FIG. 5 is a schematic cross-sectional view illustrating a semiconductor device according to a comparative example.

FIGS. 6A and 6B are schematic diagrams illustrating the characteristics of the semiconductor device according to the comparative example.

### DETAILED DESCRIPTION

Embodiments provide a semiconductor device that is capable of achieving a high breakdown voltage and lower loss.

In general, according to one embodiment, a semiconductor device includes a first semiconductor layer of a first conductivity-type, a second semiconductor layer of a second conductivity type that is selectively formed in the first semiconductor layer, a third semiconductor layer of the first conductivity type that is formed on the second semiconductor layer, and at least one control electrode that extends into the first semiconductor layer and is adjacent to sides of the second semiconductor layer and the third semiconductor layer with an insulating film located between the control electrode and the side of the second and third semiconductor layers. In addition, the semiconductor device further includes a fourth semiconductor layer of the second conductivity type that is provided on a side of the control electrode opposite to a side thereof where the second semiconductor layer is located, and a semiconductor region in at least one of a portion of the first semiconductor layer adjacent to a bottom of the control electrode with the insulating film in between and a portion of the fourth semiconductor layer adjacent the portion of the first semiconductor layer, the semiconductor region including at least one type of electrically inactive element as an impurity.

Hereinafter, an embodiment will be described with reference to the drawings. The same portions in the drawings are identified with the same numerals and the detailed descriptions thereof are appropriately omitted, and only differences are explained. It is to be noted that the drawings are schematic or conceptual drawings and the relationship between the thickness and width of each portion and the size ratio between the portions are not always identical to the actual relationships and size ratios. Moreover, even the same portion is sometimes illustrated as having different sizes or ratios in different drawings.

Furthermore, the placement and configuration of the elements of the embodiment will be described by using the X-, Y- and Z-axes illustrated in each drawing. The X-, Y- and Z-axes are perpendicular to one another and represent X, Y, and Z directions, respectively. Moreover, a description is sometimes given on the assumption that the Z direction corresponds to an upper part and the opposite direction corresponds to a lower part of a device.

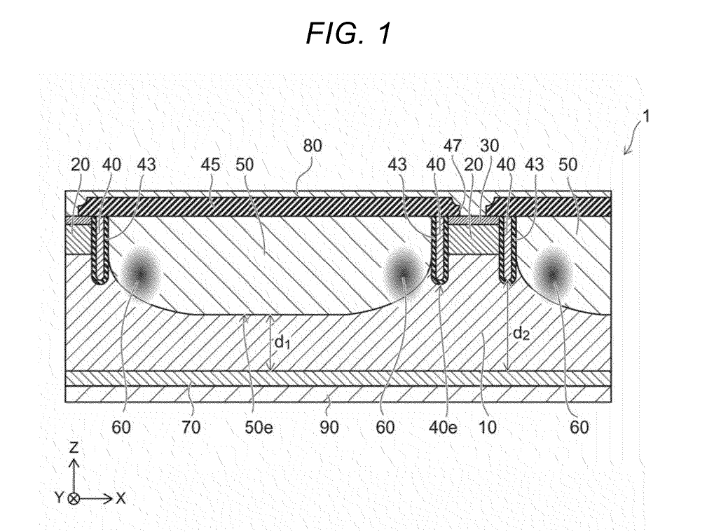

FIG. 1 is a schematic cross-sectional view illustrating a semiconductor device 1 according to the embodiment. The semiconductor device 1 is an IEGT, for example. Hereinafter, a description will be given on the assumption that a first conductivity type is an N-type and a second conductivity type is a P-type, but the conductivity type is not limited to this example. The first conductivity type may be set as the P-type and the second conductivity type may be set as the N-type.

The semiconductor device 1 includes a first semiconductor layer (hereinafter, an N-type base layer 10), a second semiconductor layer (hereinafter, a P-type base layer 20), and a third semiconductor layer (hereinafter, an N-type emitter layer 30). The P-type base layer 20 is selectively formed in the N-type base layer 10. The N-type emitter layer 30 is formed on the P-type base layer 20.

The semiconductor device 1 further includes at least one control electrode (hereinafter, a gate electrode 40) and a gate insulating film 43. The gate electrode 40 extends from the surface of the device on which the N-type emitter layer 30 is located to the inside of the N-type base layer 10. The gate electrode 40 is located adjacent to the side of the P-type base layer 20 and the N-type emitter layer 30, with the gate insulating film 43 located between the gate electrode 40 and the side of the P-type base layer 20 and the N-type emitter layer 30. Moreover, the gate electrode 40 extends inwardly of the N-type base layer 10 with the gate insulating film 43 located between the gate electrode 40 and the N-type base layer 10.

In this example, plural gate electrodes 40 are spaced apart in the X direction. Moreover, the gate electrodes 40 extend in the Y direction of the device, i.e. inwardly of the page of FIG. 1. The plural gate electrodes 40 may be connected to each other by an unillustrated portion of the device. Furthermore, the plural gate electrodes 40 may be electrically connected to one another by unillustrated gate wiring. The P-type base layer 20 and the N-type emitter layer 30 are provided between two gate electrodes 40 adjacent to each other in the X direction.

The semiconductor device 1 further includes a fourth semiconductor layer (hereinafter, a P-type floating layer 50) and a semiconductor region 60. The P-type floating layer 50 is provided on the side of the gate electrode 40 opposite to the side thereof where the P-type base layer 20 is located. That is, the P-type base layers 20 and the P-type floating layers 50 are alternately disposed between the plural gate electrodes 40 spaced in the X direction. The P-type floating layer 50 is provided on the N-type base layer 10 between adjacent gate electrodes 40.

The semiconductor region 60 is provided between a region 40e in the N-type base layer 10 and the P-type floating layer 50, the region 40e adjacent to a bottom of the gate electrode with the gate insulating film 43 in between. The semiconductor region 60 contains at least one type of electrically inactive element and formed in at least any one of the N-type base layer 10 and the P-type floating layer 50. The semiconductor region 60 may be formed over both a region in the N-type base layer 10 and a region in the P-type floating layer 50. The semiconductor region 60 contains at least one of carbon, nitrogen, and fluorine, for example.

The semiconductor device 1 further includes a fifth semiconductor layer (hereinafter, a P-type collector layer 70), an interlayer insulating film 45, a first electrode (hereinafter, an emitter electrode 80), and a second electrode (hereinafter, a collector electrode 90).

The P-type collector layer 70 is provided on the surface of the N-type base layer 10 opposite to the surface thereof where the P-type base layer 20 is located. The P-type collector layer 70 is adjacent to the N-type base layer 10, for example.

The interlayer insulating film 45 is formed to cover the gate electrode 40 and the P-type floating layer 50. The interlayer insulating film 45 has an opening 47 immediately above the N-type emitter layer 30.

The emitter electrode 80 extends over the gate electrode 40 and the P-type floating layer 50 with the interlayer insulating film 45 positioned there between. Moreover, the emitter electrode 80 covers the N-type emitter layer 30, and is directly electrically connected to the N-type emitter layer 30 through the opening 47.

The collector electrode 90 is provided on the surface of the P-type collector layer 70 opposite to the surface thereof where the N-type base layer 10 is located. The collector electrode 90 is electrically connected to the P-type collector layer 70.

Here, the P-type floating layer 50 is formed to have a deeper depth, i.e., extend further inwardly of the N type base layer 10, as compared with the depth of the gate electrodes 40 inwardly of the N-type base layer 10. That is, a distance d1 between a bottom 50e (the deepest extent inwardly of the P-type floating layer 50 into the N-type base layer 10) and the P-type collector layer 70 is shorter than a distance d2 between the bottom of the gate electrode 40 (the deepest extent of the gate electrode 40 inwardly of the N-type layer 10) and the P-type collector layer 70. Moreover, the P-type floating layer 50 is not electrically connected to the emitter electrode 80, the collector electrode 90, or to the gate electrode 40.

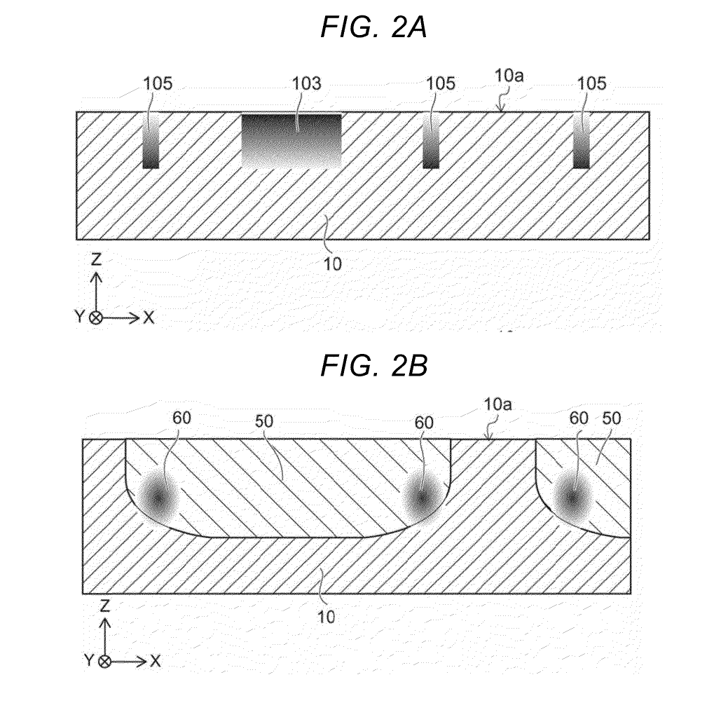

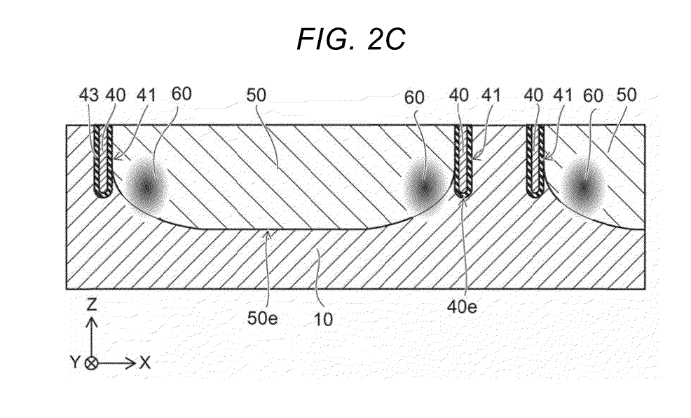

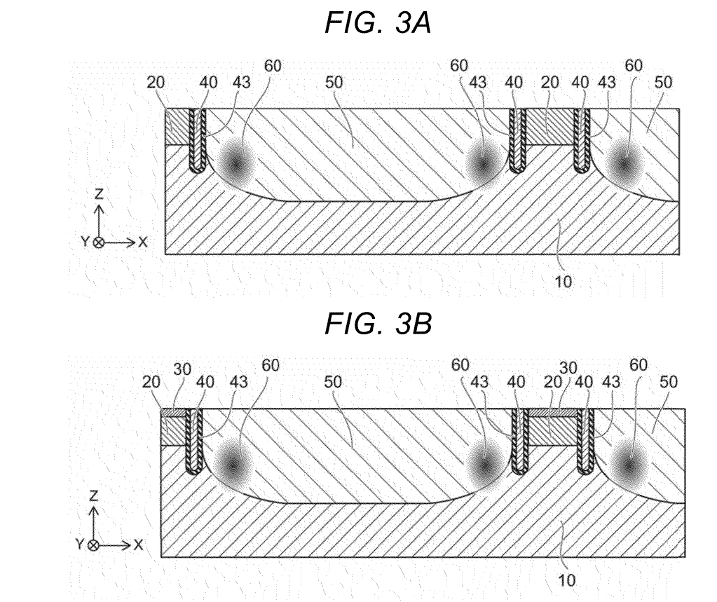

Next, with reference to FIGS. 2A to 2C and FIGS. 3A and 3B, a method for producing the semiconductor device 1 will be described. FIGS. 2A to 3B are schematic cross-sectional views each illustrating a substrate during the steps of a production process of the semiconductor device 1.

As illustrated in FIG. 2A, an N-type base layer 10 is prepared. The N-type base layer 10 may be, for example, an N-type silicon layer provided on a silicon substrate or an N-type silicon substrate.

Next, on the surface 10a of the N-type base layer 10, a P-type impurity such as boron (B11) and a neutral impurity such as carbon (C12) are separately ion-implanted. Here, the neutral impurity is, for example, an electrically inactive element in the N-type base layer 10. That is, the neutral impurity does not generate an electron or a hole, and is an electrically inactive impurity element. When the N-type base layer 10 is a silicon layer, the electrically inactive element is carbon, nitrogen, or fluorine, for example.

The P-type impurity is ion-implanted into a central region 103 between two gate electrodes 40 which are formed in a subsequent process (see FIG. 2C) and which are adjacent to each other in the X direction, for example. The ion implantation conditions for the P-type impurity (B₁₁) are, for example, implantation energy of 130 keV and a dose of 7×10¹⁴ cm⁻².

The electrically inactive element is ion-implanted into a region 105 located between a region in which the gate electrode 40 is formed in a subsequent process (see FIG. 2C) and the region 103, for example. It is preferable that the region 105 is formed near an area in which the gate electrode 40 is formed. The region 105 is formed for example in a position 1 μm away from a side surface of a gate trench 41 which is formed in a subsequent process, for example. The width of the region 105 in the X direction is 1 μm, for example.

The region 105 is formed at a position deeper into the N-type base layer 10 than the region 103, for example. For example, when the depth of the gate trench 41 is assumed to be 5.5 μm, the electrically inactive element is ion-implanted in such a way that the peak of the density distribution thereof is located at a depth of 4 to 6 μm. For example, carbon C₁₂ is ion-implanted under conditions: implantation energy of 1200 keV and a dose of 1×10¹³ cm⁻².

Next, by heat treating the N-type base layer 10, the P-type impurity is activated and dispersed therein. The heat treatment is performed under conditions: 1150° C. for 750 minutes, for example. As a result, as illustrated in FIG. 2B, it is possible to form a P-type floating layer 50 on the N-type base layer 10. The thickness (depth) of the P-type floating layer 50 in the Z direction is 11 μm, for example.

A semiconductor region 60 is formed at the same time as the formation of the P-type floating layer 50. The semiconductor region 60 is a region containing a neutral impurity, that is, an electrically inactive element. The semiconductor region 60 is formed, for example, between a region 40e of the N-type base layer 1 and the P-type floating layer 50, the region 40e being adjacent a bottom of the gate electrode 40 inwardly of the N-type base layer 10, of the gate electrode 40 formed in a subsequent process with the insulating film which is formed in a subsequent process located there between. Moreover, the semiconductor region 60 is formed near the region 40e of the N-type base layer 10. The semiconductor region 60 is formed in at least any one of the N-type base layer and the P-type floating layer 50. Furthermore, the semiconductor region 60 may be formed over both a region within the N-type base layer 10 and a region in the P-type floating layer 50.

Next, as illustrated in FIG. 2C, gate trenches 41 are formed extending inwardly of the surface 10a of the N-type base layer 10. The gate trenches 41 are formed to either side of the P-type floating layer 50. Then, a gate insulating film 43 that covers an inner surface of the gate trenches 41 is formed. Thereafter, a gate electrode 40 is formed on the gate insulating film 43 and thus embedded in trenches 41. The gate insulating film 43 is a silicon oxide film, for example. The gate electrode 40 is conductive polycrystalline silicon, for example.

As illustrated in FIG. 3A, a P-type base layer 20 is formed between adjacent gate electrodes 40, and formed on the opposite side of gate electrode 40 thereof where the P-type floating layer 50 is located. The P-type base layer 20 is formed by selectively ion-implanting boron (B), for example into the N-type base layer 10 in the region between the gate electrodes 40.

As illustrated in FIG. 3B, an N-type emitter layer 30 is formed on the P-type base layer 20 by selectively ion-implanting an N-type impurity, for example, phosphorus (P) into the uppermost portion of the p-type base layer 20. Then, an interlayer insulating film 45, a P-type collector layer 70, an emitter electrode 80, and a collector electrode 90 are formed in the configuration illustrated in FIG. 1, whereby the semiconductor device 1 is completed.

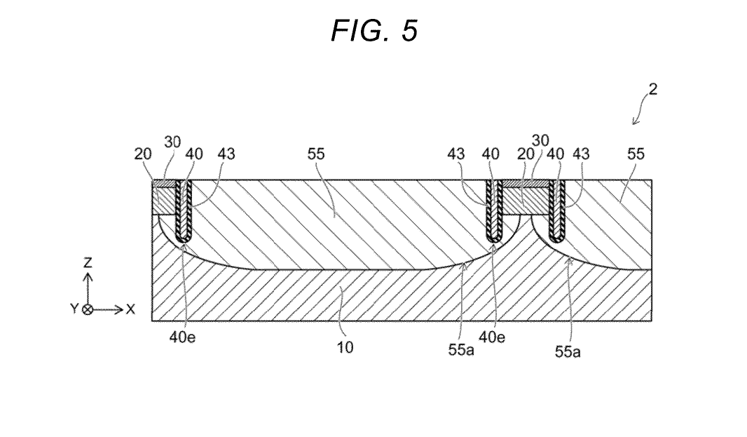

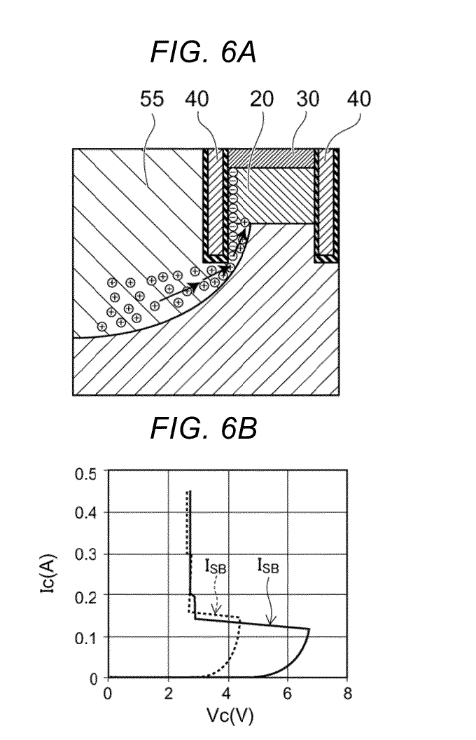

FIG. 5 is a schematic sectional view illustrating a semiconductor device 2 according to a comparative example, and FIGS. 6A and 6B are schematic diagrams illustrating the characteristics thereof.

As illustrated in FIG. 5, the semiconductor device 2 includes a P-type floating layer 55, and does not include a semiconductor region 60 as in FIG. 1. During the heat treating following ion implantation, the P-type floating layer 55 spreads under the gate electrode 40 to contact the P-type base layer 20. In other words, a surface 55a of the P-type floating layer 55 reaches the P-type base layer 20 by extending over the gate electrodes 40.

FIG. 6A is a schematic diagram illustrating the flow of carriers near the gate electrode 40 of the semiconductor device 2. FIG. 6B is a graph illustrating the current-voltage characteristics between the collector and the emitter of the semiconductor device 2. The vertical axis represents the collector current IC, and the horizontal axis represents the voltage VC between the collector and the emitter. The two characteristics illustrated in FIG. 6B indicate the current-voltage characteristics at two different locations in a wafer.

As illustrated in FIG. 6A, in the semiconductor device 2, holes do not accumulate in the P-type floating layer 55 and hole current flows from the P-type floating layer 55 toward the P-type base layer 20 through the region of the floating layer below the gate electrode 40. As a result, in the N-type base layer 10 located immediately below the P-type base layer 20, an increase of the hole accumulation is suppressed. Therefore, as illustrated in FIG. 6B, so-called snapback occurs in which a negative resistance region I_{SB} appears in the current-voltage characteristics. Such characteristics occur even when a connection between the P-type floating layer 55 and the P-type base layer 20 is generated not over the entire region of a device, but also in only a part of the device thereof.

There is concern that the effective amount of carriers of the P-type floating layer 55 is reduced if an attempt to suppress the spread of the P-type floating layer 55 in the lateral direction (the X direction) is made in order to prevent the snapback. Specifically, a method of suppressing the spread of the P-type impurities toward the gate electrode 40 by narrowing the X-direction width of the region 103 into which the P-type impurities are implanted may be possible, but this method may reduce the concentration of the P-type impurities in an area near the gate electrode 40. In such a semiconductor device, the density of the hole current flowing via the N-type base layer 10 becomes instable, resulting in an unstable forward voltage Vf.

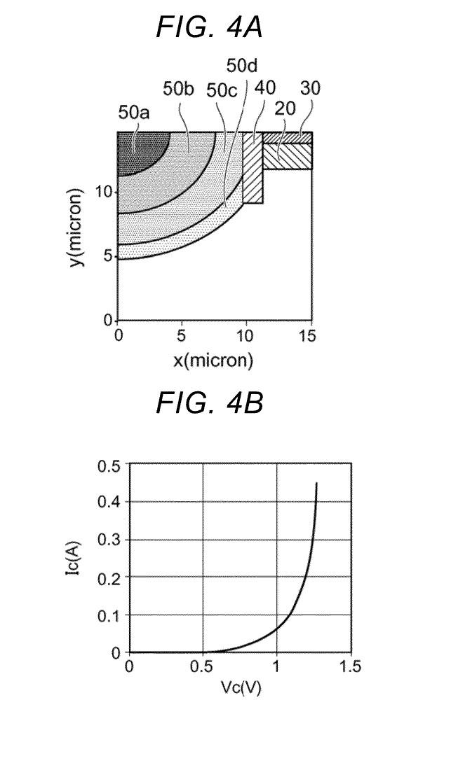

On the other hand, a schematic diagram of FIG. 4A illustrates the distribution of P-type carriers in an area near the gate electrode 40 of the semiconductor device 1. Moreover, FIG. 4B is a graph indicating the current-voltage characteristics between the collector and the emitter of the semiconductor device 1. The vertical axis represents the collector current IC and the horizontal axis represents the voltage VC between the collector and the emitter.

Regions 50a to 50d in FIG. 4A indicate the simulation results of the dopant distribution in the P-type floating layer 50. For example, in the region 50a, the concentration of the P-type dopants is about 1×10¹⁸ cm⁻³, and, in the region 50d, the concentration of the P-type dopants is about 1×10¹⁴ cm⁻³. The regions 50b and 50c have the concentrations intermediate between the concentration of the P-type dopants in the region 50a and the concentration of the P-type dopants in the region 50d. The concentration of the P-type dopants decreases from the region 50a toward the region 50d. In this example, the P-type floating layer 50 does not spread toward the P-type base layer 20 across the gate electrode 40. That is, in the semiconductor device 1, the spread of the P-type dopants in the N-type base layer 10 is suppressed by the semiconductor region 60 (the electrically inactive element existing region), and the spread of the P-type floating layer 50 in the lateral direction (the X direction) is suppressed.

As a result, the accumulation of holes is enhanced by the P-type floating layer 55, and the hole current does not directly flow from the P-type floating layer 50 into the P-type base layer 20. In addition, the holes are efficiently injected into the N-type base layer 10 located between the adjacent gate electrodes 40, and the density of the hole current is increased. Therefore, as illustrated in FIG. 4B, it is possible to obtain the current-voltage characteristics in which snapback does not occur, which are superior to the current-voltage characteristics of the comparative example of FIG. 5.

In this embodiment, by providing the semiconductor region 60, it is possible to suppress the spread of the P-type floating layer 50 under the gate electrode 40 and reaching to the emitter 20. Thereby, it possible to obtain a high-voltage and low-loss semiconductor device 1 in which the snapback is suppressed.

Furthermore, by providing the semiconductor region 60, the reliability of the resulting device is increased. For example, it has been confirmed that, in a semiconductor device in which snapback is suppressed by suppressing the spread of the P-type impurities to the emitter (p-type base layer) 20 by narrowing the X-direction width of the region 103 into which the P-type impurities are implanted, the current-voltage characteristics are degraded in a high-temperature bias test (for example, an electric current test which is conducted at 150° C. for 2000 hours) and snapback occurs. The reason is that boron gradually diffuses from the P-type floating layer in the lateral direction (the X direction) during a high-temperature operation and the resulting diffusion of the p-type dopant extends the floating layer 50 to the emitter (p-type base) layer 20 during operation of the device, inducing snapback. As described above, it has been revealed that, in the semiconductor device in the related art, even when the initial characteristics of the device are improved by narrowing the width of the p-type implanted region 105, there is a problem of device life and reliability. On the other hand, in this embodiment, the current-voltage characteristics are not degraded even in a high-temperature bias test, and high reliability of the device is achieved.

Moreover, by providing the semiconductor region 60 having electrically inactive elements therein, it is possible to increase the margin of the formation conditions of the P-type floating layer 50, that is, the ion implantation conditions and the heat treatment conditions. As a result, for example, it is possible to form the P-type floating layer 50 at the same time as the formation of a guard ring which is provided at a termination region, whereby it is also possible to shorten the production process and achieve cost reduction.

Furthermore, the embodiment is not limited to the example described above and may be applied to other devices or processes. For example, in other power semiconductor devices, it is possible to suppress the spread of impurities in the lateral direction when a deep diffusion layer is formed to achieve a high breakdown voltage. Specifically, a semiconductor region containing an electrically inactive element is formed between a guard ring diffusion layer which is formed at a termination region and a gate electrode, whereby it is possible to suppress the spread of the diffusion layer in the lateral direction while keeping the depth of the guard ring diffusion layer. Thus, it is possible to shorten the length of the termination region and achieve a reduction in chip size and on-resistance.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor layer of a first conductivity type;
a second semiconductor layer of a second conductivity type selectively formed in the first semiconductor layer;
a third semiconductor layer of the first conductivity type formed on the second semiconductor layer;
at least one control electrode that extends into the first semiconductor layer and located adjacent to the sides of the second semiconductor layer and the third semiconductor layer and an insulating film located between the control electrode and the sides of the second and third semiconductor layers;
a fourth semiconductor layer of the second conductivity type located on a side of the control electrode opposite to a side thereof at which the second semiconductor layer is located; and
a semiconductor region in at least one of a portion of the first semiconductor layer adjacent to a bottom of the control electrode with the insulating film in between, and the a portion of the fourth semiconductor layer that is adjacent the portion of the first semiconductor layer, the semiconductor region comprising at least one type of electrically inactive element therein.

2. The semiconductor device according to claim 1, wherein
the electrically inactive element in the semiconductor region is at least one of carbon, nitrogen, and fluorine.

3. The semiconductor device according to claim 2, further comprising:
a fifth semiconductor layer of the second conductivity type provided on a surface of the first semiconductor layer opposite to a surface thereof where the second semiconductor layer is located,
wherein a distance between the fourth semiconductor layer and the fifth semiconductor layer is less than a distance between the bottom of the control electrode and the fifth semiconductor layer.

4. The semiconductor device according to claim 3, further comprising plural control electrodes, wherein
the second semiconductor layer and the third semiconductor layer are provided between two adjacent control electrodes.

5. The semiconductor device according to claim 4, further comprising:
a first electrode extending over the third semiconductor layer, the fourth semiconductor layer, and the control electrode, and electrically connected to the third semiconductor layer; and
a second electrode electrically connected to the fifth semiconductor layer,
wherein the fourth semiconductor layer is not electrically connected to the first electrode, the second electrode, and the control electrode.

6. The semiconductor device according to claim 5, wherein the semiconductor region inhibits migration on the dopants in the fourth semiconductor layer into the region of the first semiconductor layer adjacent to the bottom of the control, and the control electrode is a gate electrode.

7. The semiconductor device according to claim 3, further comprising:
a first electrode extending over the third semiconductor layer, the fourth semiconductor layer, and the control electrode, and electrically connected to the third semiconductor layer; and
a second electrode electrically connected to the fifth semiconductor layer,
wherein the fourth semiconductor layer is not electrically connected to the first electrode, the second electrode, or the control electrode.

8. The semiconductor device according to claim 2, further comprising:
a first electrode extending over the third semiconductor layer, the fourth semiconductor layer, and the control electrode, and electrically connected to the third semiconductor layer; and
a second electrode electrically connected to the fifth semiconductor layer,
wherein the fourth semiconductor layer is not electrically connected to the first electrode, the second electrode, and the control electrode.

9. The semiconductor device according to claim 1, further comprising:
a fifth semiconductor layer of the second conductivity type that is provided on a surface of the first semiconductor layer opposite to a surface thereof at which the second semiconductor layer is located,
wherein a distance between the fourth semiconductor layer and the fifth semiconductor layer is less than a distance between the bottom of the control electrode and the fifth semiconductor layer.

10. The semiconductor device according to claim 9, further comprising:
a first electrode extending over the third semiconductor layer, the fourth semiconductor layer, and the control electrode, and electrically connected to the third semiconductor layer; and
a second electrode electrically connected to the fifth semiconductor layer,
wherein the fourth semiconductor layer is not electrically connected to the first electrode, the second electrode, or the control electrode.

11. The semiconductor device according to claim 10, further comprising plural control electrodes, wherein
the second semiconductor layer and the third semiconductor layer are provided between two adjacent control electrodes.

12. The semiconductor device according to claim 1, further comprising plural control electrodes, and
the second semiconductor layer and the third semiconductor layer are provided between two adjacent control electrodes.

13. The semiconductor device according to claim 1, further comprising:
a first electrode extending over the third semiconductor layer, the fourth semiconductor layer, and the control electrode, and electrically connected to the third semiconductor layer; and
a second electrode electrically connected to the fifth semiconductor layer,
wherein the fourth semiconductor layer is not electrically connected to the first electrode, the second electrode, or the control electrode.

14. The semiconductor device according to claim 1, wherein the semiconductor region inhibits migration of the dopants in the fourth semiconductor layer into the region of the first semiconductor layer adjacent to the bottom of the control electrode.

15. The semiconductor device according to claim 1, further comprising:
a second control electrode, wherein
the portion of the first semiconductor layer extends between the control electrode and the second control electrode.

16. The semiconductor device according to claim 1, wherein the control electrode is a gate electrode.

17. A method of manufacturing a semiconductor device, comprising;
providing a first semiconductor region of a first conductivity type;
providing a second semiconductor region of a second conductivity type on the first semiconductor region;
providing a third semiconductor region of the first conductivity type on the second semiconductor region;
providing a control electrode over an insulating layer extending inwardly of the first semiconductor region adjacent to a side of the second and third semiconductor regions;
providing a fourth semiconductor region of the second conductivity type adjacent to the control electrode, with the insulating layer extending therebetween, on a side of the control electrode opposed to the location of the second and third electrodes; and
providing a semiconductor region having an electrically inactive element therein in at least one of: (i) a portion of the first semiconductor region adjacent to the terminus of the control electrode inwardly of the first semiconductor region and spaced therefrom by the insulating region, and (ii) a portion of the fourth semiconductor region located adjacent to the portion of the first semiconductor region.

18. The method of claim 17, wherein the electrically inactive element in the semiconductor region is at least one of carbon, nitrogen, and fluorine.

19. The method of claim 18, further comprising:
providing a fifth semiconductor region of the second conductivity type on a surface of the first semiconductor region opposite to a surface thereof at which the second semiconductor region is located, wherein the distance between the fourth semiconductor region and the fifth semiconductor region is less than a distance between the bottom of the control electrode and the fifth semiconductor region;
providing plural control electrodes;
locating the second semiconductor region and the third semiconductor region between two adjacent control electrodes;
forming a first electrode over the third semiconductor region, the fourth semiconductor region and the control electrode, electrically connecting the first electrode to the third semiconductor region; and
forming a second electrode electrically connected to the fifth semiconductor region,
wherein the fourth semiconductor region is not electrically connected to the first electrode, the second electrode, or the control electrode.

20. The method of claim 17, further comprising:
providing a fifth semiconductor region of the second conductivity type on a surface of the first semiconductor region opposite to a surface thereof at which the second semiconductor region is located, wherein a distance between the fourth semiconductor region and the fifth semiconductor region is less than a distance between the bottom of the control electrode and the fifth semiconductor region, and
forming a first electrode to extend over the third semiconductor region, the fourth semiconductor region, and the control electrode, electrically connected to the third semiconductor region; and
forming a second electrode electrically connected to the fifth semiconductor region,
wherein the fourth semiconductor region is not electrically connected to the first electrode, the second electrode, or the control electrode.
